(19) United States
(12) Patent Application Publication
(10) Pub. No.: US 2026/0198216 A1
(43) Pub. Date: Jul. 9, 2026

(54) LOW ADHESION LAYER FOR A DISPLAY ASSEMBLY

(71) Applicant: 3M INNOVATIVE PROPERTIES COMPANY, St. Paul, MN (US)

(72) Inventor: Wei Huang, Guangdong (CN)

(21) Appl. No.: 19/133,540

(22) PCT Filed: Dec. 11, 2023
(86) PCT No.: PCT/IB2023/062496

§ 371 Date: May 28, 2025

(30) Foreign Application Priority Data
Dec. 12, 2022 (CN) 202211609674.2

(51) Int. Cl. H10K 59/80

(52) U.S. Cl. CPC H10K 59/8793; H10K 59/8722

(57) ABSTRACT

The present invention is a laminate for use with a display assembly including a pressure sensitive adhesive and a low adhesion layer positioned adjacent the pressure sensitive adhesive. The low adhesion layer has an activation temperature of between about 30 and about 80 degrees C., wherein before activation, the low adhesion layer has a water contact angle of at least about 95 degrees, and whereinafter activation, the low adhesion layer has a water contact angle of up to about 85 degrees.

### FIELD OF THE INVENTION

The present invention relates generally to the field of laminates used in display assemblies. In particular, the present invention is a laminate including a low adhesion layer for use in a display assembly.

### BACKGROUND

Within the last few years, organic light emitting diode (OLED) displays have been rapidly developing toward being used in flexible, foldable devices. This requires that the OLED stacks are fabricated on flexible devices that can be folded. Flexible electronic displays, where the display can be bent freely without cracking or breaking, is a rapidly emerging technology area for making electronic devices using, for example, flexible substrates. This technology allows integration of electronic functionality into non-planar objects, conformity to desired design, and flexibility during use that can give rise to a multitude of new applications.

With the emergence of flexible electronic displays, there is an increasing demand for adhesives, and particularly for optically clear adhesives (OCAs), to serve as an assembly layer or gap filling layer between an outer cover lens or sheet (based on glass, PET, PC, PMMA, polyimide, PEN, cyclic olefin copolymer, etc.) and an underlying display module of electronic display assemblies. The presence of the OCA improves the performance of the display by increasing brightness and contrast, while also providing structural support to the assembly. In a flexible assembly, the OCA will also serve at the assembly layer, which in addition to the typical OCA functions, may also absorb most of the folding induced stress to prevent damage to the fragile components of the display panel and protect the electronic components from breaking under the stress of folding. The OCA layer may also be used to position and retain the neutral bending axis at or at least near the fragile components of the display, such as for example the barrier layers, the driving electrodes, or the thin film transistors of an OLED. The adhesion is very important as any extra stresses can damage the OLED stack during the removal process. With flexible and curved displays, the OCA must have high adhesion in order to resist stress. At the same time, because of the high adhesion, the possibility that the flexible OLED panel may break during rework increases.

### SUMMARY

In one embodiment, the present invention is a laminate for use with a display assembly including a pressure sensitive adhesive and a low adhesion layer positioned adjacent the pressure sensitive adhesive. The low adhesion layer has an activation temperature of between about 30 and about 80 degrees C., wherein before activation, the low adhesion layer has a water contact angle of at least about 95 degrees, and whereinafter activation, the low adhesion layer has a water contact angle of up to about 85 degrees.

In another embodiment, the present invention is a display assembly including a cover glass, a laminate positioned adjacent the cover glass, and an OLED panel positioned adjacent the laminate. The laminate includes an optically clear first pressure sensitive adhesive and a low adhesion layer. The low adhesion layer has an activation temperature of between about 30 and about 80 degrees C. Before activation, the first optically clear pressure sensitive adhesive has a 180 degree peel strength of up to about 2N/inch on the low adhesion layer. After activation, the first optically clear pressure sensitive adhesive has a 180 degree peel strength of at least about 10N/inch on the low adhesion layer.

### BRIEF DESCRIPTION OF THE DRAWING

The figure is not drawn to scale and is intended merely for illustrative purposes. The disclosure may be more completely understood in consideration of the following detailed description of various embodiments of the disclosure in connection with the accompanying drawing, in which:

FIG. 1A is a cross-sectional view of a first embodiment of a display assembly including the laminate of the present invention.

FIG. 1B is a cross-sectional view of a second embodiment of a display assembly including the laminate of the present invention.

FIG. 2A is a cross-sectional view of a third embodiment of a display assembly including the laminate of the present invention.

FIG. 2B is a cross-sectional view of a fourth embodiment of a display assembly including the laminate of the present invention.

In the following detailed description, reference may be made to the accompanying drawing that forms a part hereof and in which is shown by way of illustration a specific embodiment. It is to be understood that other embodiments are contemplated and may be made without departing from the scope or spirit of the present disclosure.

### DETAILED DESCRIPTION

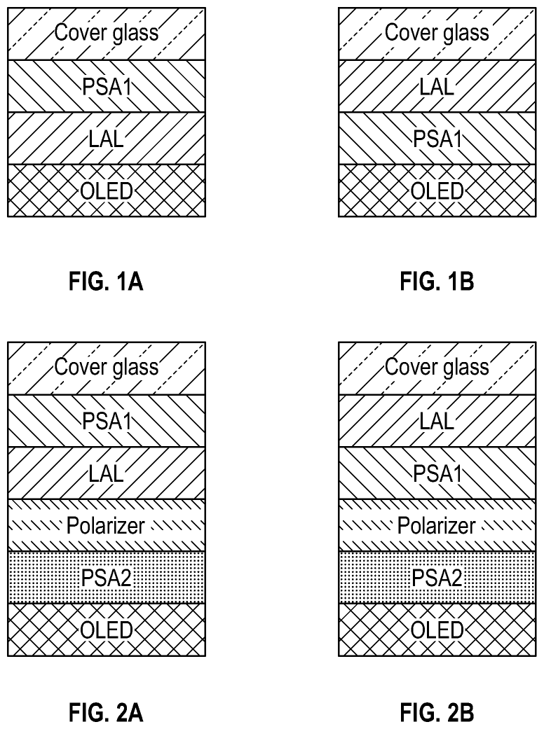

FIGS. 1A and 1B show cross-sectional views of first and a second embodiments of a display assembly including the laminate of the present invention. The laminate allows for reworkability, making it suitable for use with a display assembly that may require or benefit from repositioning layers during processing. The display assembly generally includes a cover glass, a first pressure sensitive adhesive, a low adhesion layer, and an OLED panel. In yet another pair of embodiments shown in FIGS. 2A and 2B, the display assembly also includes a polarizer positioned adjacent to the OLED panel via a second pressure sensitive adhesive layer. The polarizer, second pressure sensitive adhesive, and OLED panel are then attached to the cover glass via the laminate. The laminate of the present invention provides rework feasibility to the display assembly while maintaining high adhesion performance.

The laminate of the present invention includes the first pressure sensitive adhesive and the low adhesion layer. In all embodiments of the present invention, the low adhesion layer is positioned immediately adjacent the first pressure sensitive adhesive and functions to allow reworkability between the cover glass and the OLED panel. The low adhesion layer is heat-susceptible and is interposed between the first pressure sensitive adhesive and another substrate, such as a cover glass (shown in FIGS. 1B and 2B), polarizer (shown in FIG. 2A) or encapsulation of OLED (glass or thin film encapsulation) (shown in FIG. 1A). The heat-susceptible low adhesion layer provides a low surface energy layer and has low adhesion to the substrate prior to heat exposure such that the assembly can be manually peeled apart at the interface between the low adhesion layer and the first pressure sensitive adhesive. However, the low adhesion layer still has sufficient adhesion to the substrate such that the substrate can be held to the laminate under normal handling conditions.

Upon heating the display assembly to an elevated temperature, or the activation temperature of the low adhesion layer, the low adhesion layer and the first pressure sensitive adhesive develop a firm and long-lasting bond. This is due to the fact that at the activation temperature, the low adhesion layer and the first pressure sensitive adhesive have sufficient wetting. As the temperature increases to the activation temperature, wetting increases and accelerates the formation of secondary bonds between the low adhesion layer and the first pressure sensitive adhesive. Secondary bonds can be characterized by measured adhesion, such as 180 degree peel strength.

In one embodiment, the low adhesion layer has an activation temperature of between about 30 and about 80 degrees C. and particularly between about 60 and about 80 degrees C. Within this temperature range, there is generally no conflict with the typical autoclaving process, there is a shorter heating time, and there is no damage to the display. The low adhesion layer is activated upon heating to or above the activation temperature of the low adhesion layer. Before activation, the first pressure sensitive adhesive has a 180 degree peel strength of up to about 2N/inch and particularly of up to about 1.5N/inch on the low adhesion layer. After activation, the low adhesion layer and first pressure sensitive adhesive develop a long-lasting bond which remains after cooling. Once cooled to room temperature, the first pressure sensitive adhesive has a 180 degree peel strength of at least about 10N/inch and particularly of up to about 12.5N/inch on low adhesion layer. Generally, the 180 degree peel strength is affected by the substrate (i.e., the low adhesion layer in this case) and the adhesive. For the values measured above, the 180 degree peel strength is measured using a modified ASTM D3330 (method E portion) where a 0.002 inch thick polyester film is used as the backing, the low adhesion layer is used as the substrate, and CEF30, available from 3M Company, St. Paul, MN, is used as the adhesive. The measurement is the strength needed to peel the adhesive from the low adhesion layer.

As mentioned above, the bond between the low adhesion layer and the first pressure sensitive adhesive is dependent at least in part on wetting. A smaller water contact angle generally means that the low adhesion layer is more easily wetted. The activation temperature of the low adhesion layer affects the water contact angle of the low adhesion layer. Before activation, the low adhesion layer has a water contact angle of at least about 95 degrees and particularly of at least about 100 degrees. After activation, the low adhesion layer has a water contact angle of up to about 85 degrees and particularly up to about 80 degrees. The water contact angle is affected by the substrate (low adhesion layer), purity of the water, temperature, and humidity and can be measured using ASTM D7490.

Many materials are known that may be coated or layered onto a substrate to provide a surface having low adhesion toward a pressure sensitive adhesive. For example, such materials have been used for many years as “low-adhesion backsizes” on backings for pressure-sensitive adhesive tapes to prevent the backings from adhering to overlying layers of tape when the tape is wound in a roll. Generally, sheet material treated with a low-adhesion backsize have an adhesion of less than about 10 ounces/inch width to the adhesive layer which it is intended to contact. In any event, the adhesion is sufficiently low in products of the invention so that the laminate may be manually peeled apart. In one embodiment, the low adhesion layer of the present invention is a silicone or a C18-based polymer. Examples of suitable low adhesion layers include, but are not limited to: silicone copolymers, modified silicones, and long alkyl side chain polymers. An example of a suitable low adhesion layer includes, but is not limited to, a long alkyl side chain polyurethane having an octadecyl (C18) side chain. In one embodiment, the low adhesion layer has a thickness of about 0.01 mm or less.

In one embodiment, the low adhesion layer and/or the first and/or second pressure sensitive adhesive is optically clear. As used herein, the term “optically clear” refers to a material that has a haze of less than about 6%, particularly less than about 4% and more particularly less than about 2%; a luminous transmission of greater than about 88%, particularly greater than about 89%, and more particularly greater than about 90%; and an optical clarity of greater than about 98%, particularly greater than about 99%, and more 20 particularly greater than about 99.5% when cured. Typically, the clarity, haze, and transmission are measured on a construction in which the layer is held between two optical glass plates or two optical films, such as poly(ethylene terephthalate) (PET). The measurement is then taken on the entire construction. Both the haze and the luminous transmission can be determined using, for example, ASTM-D 1003-92. The optical measurements of transmission, haze, and optical clarity can be made using, for example, a BYK Gardner haze-gard plus 4725 instrument (Geretsried, Germany). The BYK instrument uses an illuminant “C” source and measures all the light over that spectral range to calculate a transmission value. Haze is the percentage of transmitted light that deviates from the incident beam by more than 2.5°. Optical clarity is evaluated at angles of less than 2.5°.

In practice, the laminate is used within a display assembly. A first surface of the low adhesion layer is positioned adjacent the first pressure sensitive adhesive and a second, opposing surface of the low adhesion layer is positioned adjacent the cover glass (FIGS. 1B and 2B), polarizer (FIG. 2A) or encapsulation of OLED panel (FIG. 1A). Before activation, the low adhesion layer and the first pressure sensitive adhesive can be manually peeled apart and reworked as needed. Once the layers are properly positioned, the display assembly is heated to the activation temperature of the low adhesion layer, bonding the low adhesion layer and the first pressure sensitive adhesive. At the elevated temperature and after cooling back to room temperature, the low adhesion layer and the first pressure sensitive adhesive can no longer be manually peeled apart intact due to a strong bond developed between the low adhesion layer and the first pressure sensitive adhesive. In fact, in some embodiments, the bond that develops is of greater strength than would have developed during heating in the absence of the low adhesion layer.

In one embodiment, a display assembly is configured by first coating the low adhesion layer on the surface of a polarizer and dried. The low adhesion layer can be coated by one of slot die coating, gravure coating, spray or inkjet. The polarizer can be a jumbo or converted part. In one embodiment, the drying temperature can be about 50 to about 120 degrees C. The polarizer is then converted to a suitable size and laminated to an OLED panel with a roller wherein, for example, the pressure is about 0.1M Pa to about 0.5M Pa, speed is about 0.1 m/min to about 3 m/min. An optically clear adhesive is laminated to the cover glass with a roller wherein, for example, the pressure is about 0.1M Pa to about 0.5M Pa, speed is about 0.1 m/min to about 3 m/min. The above components are bonded together in a vacuum environment wherein, for example, the vacuum degree is less than about 300 Pa and wherein the bonding pressure is about 0.1M Pa to about 1M Pa. The above module is then put in an autoclave machine, wherein the pressure is, for example. 0.1 to 1M Pa, the temperature is about 30 to 60 degrees C., and the time is about 5 to 60 minutes. The above module is subjected to the activation temperature, about 60 to 80 degrees C. and the time is about 10 to 30 minutes.

In another embodiment, a display assembly is configured by first coating the low adhesion layer on a cover glass and dried. The low adhesion layer can be coated by one of slot die coating, gravure coating, spray or inkjet. In one embodiment, the drying temperature can be about 50 to about 120 degrees C. The polarizer is then laminated to an OLED panel with a roller wherein, for example, the pressure is about 0.1M Pa to about 0.5M Pa, speed is about 0.1 m/min to about 3 m/min. An optically clear adhesive is laminated to the cover glass with a roller wherein, for example, the pressure is about 0.1M Pa to about 0.5M Pa, speed is about 0.1 m/min to about 3 m/min. The above components are bonded together in a vacuum environment wherein, for example, the vacuum degree is less than about 300 Pa and wherein the bonding pressure is about 0.1M Pa to about 1M Pa. The above module is then put in an autoclave machine, wherein the pressure is, for example. 0.1 to 1M Pa, the temperature is about 30 to 60 degrees C., and the time is about 5 to 60 minutes. The above module is subjected to the activation temperature, about 60 to 80 degrees C. and the time is about 10 to 30 minutes.

In another embodiment, a display assembly is configured by first coating the low adhesion layer an OLED panel and dried. The low adhesion layer can be coated by one of slot die coating, gravure coating, spray or inkjet. In one embodiment, the drying temperature can be about 50 to about 120 degrees C. An optically clear adhesive is laminated to the cover glass with a roller wherein, for example, the pressure is about 0.1M Pa to about 0.5M Pa, speed is about 0.1 m/min to about 3 m/min. The above components are bonded together in a vacuum environment wherein, for example, the vacuum degree is less than about 300 Pa and wherein the bonding pressure is about 0.1M Pa to about 1 M Pa. The above module is then put in an autoclave machine, wherein the pressure is, for example. 0.1 to 1 M Pa, the temperature is about 30 to 60 degrees C., and the time is about 5 to 60 minutes. The above module is subjected to the activation temperature, about 60 to 80 degrees C. and the time is about 10 to 30 minutes.

In another embodiment, a display assembly is configured by first coating the low adhesion layer on a cover glass and dried. The low adhesion layer can be coated by one of slot die coating, gravure coating, spray or inkjet. In one embodiment, the drying temperature can be about 50 to about 120 degrees C. An optically clear adhesive is laminated to the cover glass with a roller wherein, for example, the pressure is about 0.1M Pa to about 0.5M Pa, speed is about 0.1 m/min to about 3 m/min. The above components are bonded together in a vacuum environment wherein, for example, the vacuum degree is less than about 300 Pa and wherein the bonding pressure is about 0.1M Pa to about 1M Pa. The above module is then put in an autoclave machine, wherein the pressure is, for example. 0.1 to 1M Pa, the temperature is about 30 to 60 degrees C., and the time is about 5 to 60 minutes. The above module is subjected to the activation temperature, about 60 to 80 degrees C. and the time is about 10 to 30 minutes.

### Examples

The present invention is more particularly described in the following examples that are intended as illustrations only, since numerous modifications and variations within the scope of the present invention will be apparent to those skilled in the art. Unless otherwise noted, all parts, percentages, and ratios reported in the following examples are on a weight basis.

TABLE 1
Materials

| Abbreviation | Description and Source |
|---|---|
| PVOD | Poly(vinyl N-octadecylcarbamate), available under the trade |
| | designation “Sigma-Aldrich ®” from Sigma-Aldrich |
| | (Shanghai) Trading Co. Ltd., Shanghai, China |
| CEF30 | Optical clear adhesive CEF3006AS, available from 3M |
| | Company, St. Paul, MN |
| CG | Cover glass, available under the trade designation |
| | “Gorilla ® Glass” from Corning Company, NY |
| POL | Polarizer, available from Sumitomo Chemical Company, |
| | Tokyo, Japan |
| OLED | Organic Light-Emitting Diode panel from disassembled |
| | smart phone, available under the trade designation “Xiaomi |
| | 10” from Xiaomi Company, Beijing, China |

### Test Methods

### Method for Determining Thickness

The thickness of the low adhesion layer (LAL) was measured using a thickness meter (obtained under the trade designation “547-401” from Mitutoyo Corporation, Kanagawa, Japan). The LAL used for these measurements were coated on substrates and the total thickness was measured. Prior to coating, the substrate thickness was measured.

The LAL thickness is the difference between total thickness and substrate thickness. Thickness values are reported as an average of measurements at three different locations on the sample plus or minus one standard deviation.

### Method for Determining the Water Contact Angle

The water contact angle (WCA) was measured using a WCA meter (obtained under the trade designation “JC2000D” from Shanghai Zhongchen Corporation, Shanghai, China). The test method is based on ASTM D5946. 2-3 μL of pure water was injected to the material's surface and an image of a droplet was taken using CCD camera of WCA meter. WCA was measured and analyzed directly with a protractor by using tangential alignment of a cursor line.

### Method for Determining the 180 Degree Peel Strength

The 180 degree peel strength was measured using a materials testing system (obtained under the trade designation “3400” from Instron Company, Norwood, MA). The test method is based on ASTM D3330. The sample width was 25 mm. The easy liner of the OCA was removed and superimposed on the test strip of nominal 0.050 mm thick polyester film. This film was laminated to test materials with a 1 kg roller and allowed to dwell for 20 minutes. The folded end of the film was doubled backed at an angle of 180° and peeled from the test materials at a speed of 305 mm/minute.

### General Method for Preparing LAL Coatings

The LAL was made using a bar coater (obtained under the trade designation “AB4120 AFA” from TQC Sheen Company, Rotterdam, Netherlands). The target substrate was placed on the platform of the bar coater and the solution of LAL was poured on the substrate. The bar moved automatically and created a flat surface. The sample was then dried at 80° C. for 10 minutes.

### Preparative Example (PE)

A toluene solution containing 5 wt. % of PVOD was prepared by first placing 5.0 grams of PVOD in a 250 ml beaker. 95.0 grams toluene was then added and blended until the PVOD dissolved.

### Examples 1-3 (EX-1, EX-2, EX-3)

To create Examples 1-3, PE was coated on substrates using the coating method described above on the respective substrates indicated in Table 2. The samples were dwelled for 24 hours at room temperature.

The WCA of each of the LALs of Examples 1-3 were measured using a WCA meter as described above. The WCA measurements before activation are listed in Table 2.

CEF30 was then laminated on the surface of the LAL of Examples 1-3 using a 1 kg roller. The samples were dwelled for 20 minutes and the 180 degree peel strength was measured using the method described above. The measurements before activation are listed in Table 2.

The LAL of each of Examples 1-3 was activated at 80° C. for 10 minutes. The WCA was then measured with the measurements after activation listed in Table 2.

CEF30 was then laminated on the surface of the LAL of Examples 1-3 using a 1 kg roller at a speed of 1 m/minute. The LAL of each of Examples 1-3 was activated at 80° C. for 10 minutes and allowed to dwell for 20 minutes at room temperature. The 180 degree peel strength was then measured, with the measurements after activation listed in Table 2.

### Comparative Examples

The WCAs of the substrates of Comparative Examples A-C were measured using a WCA meter as described above. The measurements before activation are listed in Table 2. Comparative Examples A-C did not include a LAL and were therefore not activated.

CEF30 was laminated on the surfaces of Comparative Examples A-C using a 1 kg roller and allowed to dwell for 20 minutes. The 180 degree peel strength was measured using the method described above, with the measurements before activation listed in Table 2. Comparative Examples A-C did not include a LAL and were therefore not activated.

TABLE 2
Measurements

| | | | Water Contact Angle (WCA) | | 180 Degree Peel Strength, | |
|---|---|---|---|---|---|---|
| | | LAL | [degrees] | | [N/inch] | |
| | | thickness | Before | After | Before | After |
| Example | Substrate | [μm] | Activation | Activation | Activation | Activation |
| EX-1 | CG | 5 | 106 | 80 | 0.79 | 13.3 |
| EX-2 | POL | 5 | 105 | 79 | 0.81 | 13.1 |
| EX-3 | OLED | 6 | 108 | 83 | 0.73 | 12.7 |
| CE-A | CG | NA | 68 | NA | 31.21 | NA |
| CE-B | POL | NA | 96 | NA | 12.82 | NA |
| CE-C | OLED | NA | 82 | NA | 27.17 | NA |

Although the present invention has been described with reference to preferred embodiments, workers skilled in the art will recognize that changes may be made in form and detail without departing from the spirit and scope of the invention.

What is claimed is:

1. A laminate for use with a display assembly comprising:
a pressure sensitive adhesive; and
a low adhesion layer positioned adjacent the pressure sensitive adhesive,
wherein the low adhesion layer has an activation temperature of between about 30 and about 80 degrees C., wherein before activation, the low adhesion layer has a water contact angle of at least about 95 degrees, and whereinafter activation, the low adhesion layer has a water contact angle of up to about 85 degrees.

2. The laminate of claim 1, wherein the low adhesion layer and the pressure sensitive adhesive are optically clear.

3. The laminate of claim 1, further comprising a polarizer.

4. The laminate of claim 3, wherein the polarizer is positioned adjacent the pressure sensitive adhesive.

5. The laminate of claim 3, wherein the polarizer is positioned adjacent the low adhesion layer.

6. The laminate of claim 1, wherein before activation, the pressure sensitive adhesive has a 180 degree peel strength of up to about 2N/inch on the low adhesion layer, and wherein after activation, pressure sensitive adhesive has a 180 degree peel strength of at least about 10N/inch on the low adhesion layer.

7. The laminate of claim 1, wherein before activation, pressure sensitive adhesive has a 180 degree peel strength of up to about 1.5N/inch on the low adhesion layer, and wherein after activation, the pressure sensitive adhesive has a 180 degree peel strength of at least about 12.5N/inch on the low adhesion layer.

8. The laminate of claim 1, wherein before activation, the low adhesion layer has a water contact angle of at least about 100 degrees, and wherein after activation, the low adhesion layer has a water contact angle of up to about 80 degrees.

9. The laminate of claim 1, wherein the low adhesion layer has a thickness of about 0.01 mm or less.

10. The laminate of claim 1, wherein the low adhesion layer is a silicone or a C18-based polymer.

11. The laminate of claim 10, wherein the low adhesion layer is one of a silicone copolymer, modified silicone, and long alkyl side chain polymer.

12. The laminate of claim 11, wherein the low adhesion layer is a long alkyl side chain polyurethane having an octadecyl (C18) side chain.

13. The laminate of claim 1, wherein the low adhesion layer has an activation temperature of between about 60 to about 80 degrees C.

14. A display assembly comprising:
a cover glass;
a laminate positioned adjacent the cover glass, wherein the laminate comprises:
an optically clear first pressure sensitive adhesive; and
a low adhesion layer,
wherein the low adhesion layer has an activation temperature of between about 30 and about 80 degrees C., wherein before activation, the first optically clear pressure sensitive adhesive has a 180 degree peel strength of up to about 2N/inch on the low adhesion layer, and wherein after activation, the first optically clear pressure sensitive adhesive has a 180 degree peel strength of at least about 10N/inch on the low adhesion layer; and
an OLED panel positioned adjacent the laminate.

15. The display assembly of claim 14, further comprising a polarizer positioned between the laminate and the OLED panel.

16. The display assembly of claim 14, further comprising a second optically clear pressure sensitive adhesive positioned between the polarizer and the OLED panel.

17. The display assembly of claim 14, wherein the low adhesion layer has an activation temperature of between about 60 to about 80 degrees C.

18. The display assembly of claim 14, wherein the low adhesion layer is a silicone or a C18-based polymer.

19. The display assembly of claim 14, wherein before activation, the low adhesion layer has a water contact angle of at least about 95 degrees, and whereinafter activation, the low adhesion layer has a water contact angle of up to about 85 degrees.

20. The display assembly of claim 14, wherein before activation, the first optically clear pressure sensitive adhesive has a 180 degree peel strength of up to about 1.5N/inch on the low adhesion layer, and wherein after activation, the first optically clear pressure sensitive adhesive has a 180 degree peel strength of at least about 12.5N/inch on the low adhesion layer.
